(19) United States
(12) Patent Application Publication
(10) Pub. No.: US 2019/0343026 A1
(43) Pub. Date: Nov. 7, 2019

(54) LIQUID COOLING SYSTEM FOR CABINET SERVER

(71) Applicants: Inventec (Pudong) Technology Corporation, Shanghai City (CN); Inventec Corporation, Taipei City (TW)

(72) Inventors: Xiu-Hua Zhao, Shanghai City (CN); Ji-Peng Xu, Shanghai City (CN); Jia-Bin Wang, Shanghai City (CN); Dong-Rui Xue, Shanghai City (CN); Lian-Fei Zhang, Shanghai City (CN); Pin-Yi Xiang, Shanghai City (CN)

(73) Assignees: Inventec (Pudong) Technology Corporation, Shanghai City (CN); Inventec Corporation, Taipei City (TW)

(21) Appl. No.: 16/142,214

(22) Filed: Sep. 26, 2018

(30) Foreign Application Priority Data
May 4, 2018 (CN) 201810420096.5

(51) Int. Cl. H05K 7/20

(52) U.S. Cl. CPC H05K 7/20781; H05K 7/20272; H05K 7/20836

(57) ABSTRACT

The present application discloses a liquid cooling system for a cabinet server, which includes a primary side liquid circulation pipe, a distribution control device, and a secondary side liquid circulation pipe, and the primary side liquid circulation pipe is connected to the water filling device. The distribution control device is connected to the primary side liquid circulation pipe, and the secondary side liquid circulation pipe is connected to the distribution control device and at least one cabinet server. The liquid cooling system of the present application cools the cabinet server by liquid cooling, and the energy efficiency ratio of the liquid cooling system is below 1.3, there is almost no noise, no low filling water temperature is needed, natural cooling source is fully utilized, and the cooling tower can be used to meet the heat dissipation requirement.

### RELATED APPLICATIONS

This application claims priority to China Application CN201810420096.5, filed on May 4, 2018, which is incorporated by reference herein in its entirety.

### BACKGROUND

### Technical Field

The present disclosure relates to the technical field of cabinet server systems, and more particularly to a liquid cooling system for a cabinet server.

### Related Art

At present, most of the data centers use air-cooled air conditioning systems to dissipate heat from the cabinet servers. The air-cooled air conditioning system uses the rotation of the fans to drive air flow, to take away the heat of the cabinet servers. From the perspective of cooling, the main energy consumption of air-cooling is generated by air-cooled outdoor condensers, air conditioners, compressors, etc., resulting in a relatively low energy efficiency of the stand-alone system. Currently, the power usage effectiveness (PUE) commonly used air-cooling method is about 1.5-2.0.

Conventional air-cooling and heat-dissipating technology is relatively mature, and the energy consumption and noise problem brought by the fan of the air-cooling system have seriously hindered the improvement of computer performance. The research shows that the relationship between heat transfer coefficient and wind speed is h∝u^{0.8}, the relationship between pressure loss and wind speed is ΔP∝u², and the relationship between noise and wind speed is U∝u⁵, which will not meet the development of high performance computer. In addition, for high-performance servers, due to the increased power consumption of CPUs/DIMMs and the introduction of expansion cards with strong computing and storage performance, heat dissipation has become a significant challenge for server design and application. For ultra-high power density data centers, air-cooling technology is difficult to achieve efficient heat dissipation.

### SUMMARY

The main purpose of the present disclosure is to provide a liquid cooling system for a cabinet server, which solves the problems in the prior art that air cooling is difficult to achieve high efficiency heat dissipation.

In order to solve the above technical problems, the present disclosure is implemented as follows:

A liquid cooling system provided for a cabinet server, comprising: a primary side liquid circulation pipe connected to the water filling device; a distribution control device connected to the primary side liquid circulation pipe; and a secondary side liquid circulation pipe connected to the distribution control device and the at least one cabinet server; wherein the primary side liquid circulation pipe inputs the first cooling liquid to the distribution control device, and the secondary side liquid circulation pipe inputs the second cooling liquid to each of the cabinet servers, The second cooling liquid flows through at least one server of the corresponding cabinet server, and the cabinet server outputs the liquid to be cooled to the secondary side liquid circulation pipe, and the liquid to be cooled passes through the secondary liquid circulation pipe to the distribution control device, and the heat exchange of the first cooling liquid and the liquid to be cooled is performed in the distribution control device and the distribution control device provides the cooling liquid that has gone through heat exchange to the secondary liquid circulation pipe.

In the embodiment of the present disclosure, the cabinet server is cooled by the liquid cooling method, and the energy-efficiency ratio of the liquid cooling system is less than 1.3, there is almost no noise, no low filling water temperature is needed, the natural cold source is fully utilized, and the cooling tower can be used to meet the heat dissipation requirement. This disclosure uses liquid cooling to replace the air conditioning system, and the liquid cooling system occupies less space in the cabinet server, so that the cabinet server can accommodate more servers. The liquid cooling system of the present disclosure has a good cooling capacity, improves the heat flux density of the data center of the machine, saves the floor space, and is not restricted by altitude and geography, and can work normally anywhere.

### BRIEF DESCRIPTION OF THE DRAWINGS

The present disclosure will become more fully understood from the detailed description given here in below and the accompanying drawings which are given by way of illustration only and thus are not limitative of the present disclosure and wherein:

FIG. 1 is a schematic view of a liquid cooling system according to an embodiment of the present disclosure.

FIG. 2 is a schematic diagram of a distribution control device according to an embodiment of the present disclosure.

FIG. 3 is a schematic diagram of a secondary side liquid circulation pipe connected to a cabinet server according to an embodiment of the present disclosure.

FIG. 4 is a schematic diagram of a server according to an embodiment of the present disclosure.

FIG. 5 is a flow chart showing temperature control by the distribution control device according to an embodiment of the present disclosure.

FIG. 6 is a flow chart showing a first mode of flow control by the distribution control device according to the embodiment of the present disclosure.

FIG. 7 is a flow chart showing a second mode of flow control by the distribution control device according to the embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The use of “first”, “second”, etc., as used herein, does not specifically mean the order, and is not intended to limit the disclosure, but merely to distinguish components or operations described in the same technical terms.

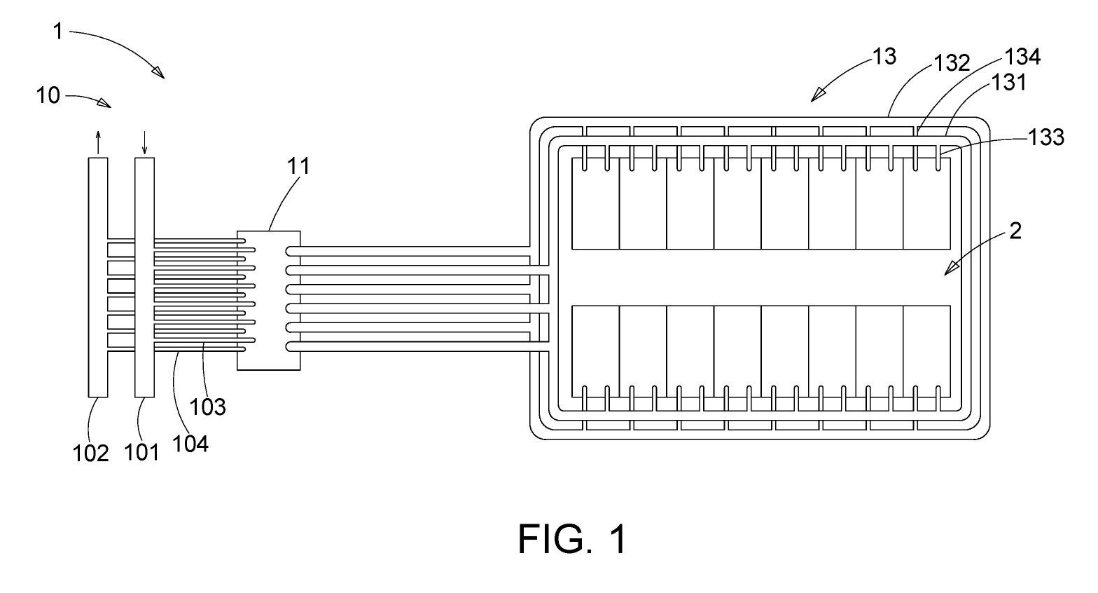

Please refer to FIG. 1, which is a schematic diagram of a liquid cooling system according to an embodiment of the present disclosure. As shown in the figure, the present embodiment provides a liquid cooling system 1 for a cabinet server, and the liquid cooling system 1 includes a primary side liquid circulation pipe 10, the distribution control device 11, and the secondary side liquid circulation pipe 13, one end of the primary side liquid circulation pipe 10 and the secondary side liquid circulation pipe 13 are connected to the distribution control device 11, and the other end of the primary side liquid circulation line 10 is connected to the water filling device, and the other end of the secondary side liquid circulation pipe 13 is connected to at least one cabinet server 2. The water filling device supplies a first cooling liquid to the primary side liquid circulation pipe 10, and the first cooling liquid is input into the distribution control device 11 through the primary side liquid circulation pipe 10. The secondary side liquid circulation pipe 13 supplies and inputs a second cooling liquid to each of the cabinet servers 2, and the second cooling liquid flows through at least one of the servers of the corresponding cabinet server 2, gives out a liquid to be cooled. The cabinet server 2 outputs the liquid to be cooled to the secondary liquid circulation pipe 13, and the liquid to be cooled passes through the secondary liquid circulation pipe 13 to the distribution control device 11, and heat exchange of the first cooling liquid and the liquid to be cooled takes place inside the distribution control device 11, and a new second cooling liquid is produced. The distribution control device 11 provides a new second cooling liquid to the secondary side liquid circulation pipe 13 so that the secondary side liquid circulation pipe 13 can continuously supply the second cooling liquid to the at least one cabinet server 2, which can be efficiently reduced at least one cabinet server's 2 temperature, thus increases heat dissipation efficiency.

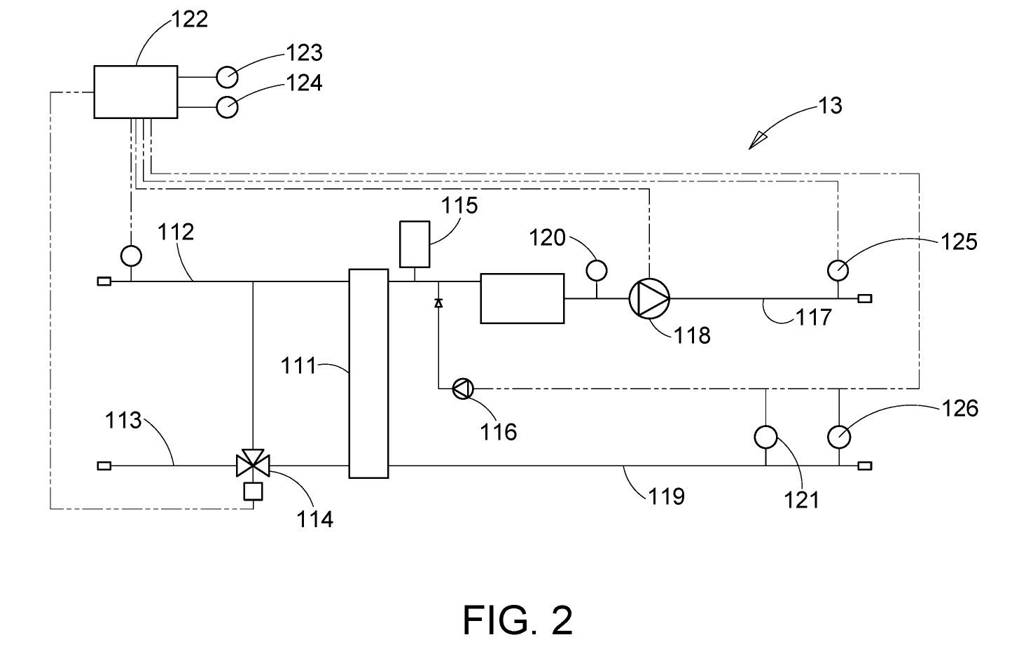

The configuration of the primary side liquid circulation pipe 10, the distribution control device 11, and the secondary side liquid circulation pipe 13 will be described in detail below. Refer to FIG. 2, a schematic diagram of a distribution control device according to an embodiment of the present disclosure; as shown, the distribution control device 11 includes a heat exchanger 111, a primary side input pipe 112, and a primary side output pipe 113, primary side control valve 114, water tank 115, first pump 116, secondary side output pipe 117, second pump 118, secondary side input pipe 119, first temperature sensor 120, second temperature sensor 121, logic controller 122, surrounding temperature sensor 123, and surrounding humidity sensor 124. One end of the primary side input pipe 112 and the primary side output pipe 113 are respectively connected to the heat exchanger 111, and the primary side control valve 114 is connected to the primary side input pipe 112 and the primary side output pipe 113 through a pipeline to control the input of the primary side input pipe 112 and the output of the primary side output pipe 113. The primary side input pipe 112, the primary side output pipe 113, and the primary side control valve 114 are all located on the primary side of the heat exchanger 111.

The water tank 115 is connected to the secondary side of the heat exchanger 111, the first pump 116 is connected to the water tank 115 and the water filling device, the second pump 118 is connected to the water tank 115 through a pipeline, and the secondary side output pipe 117 is connected to the second pump 118. The secondary side input pipe 119 is connected to the heat exchanger 111. The first temperature sensor 120 is disposed in the secondary side output pipe 117 to measure the temperature of the liquid flowing in the secondary side output pipe 117. In other words, the first temperature sensor 120 measures the temperature of the second cooling liquid circulate from the distribution control device 11 to the secondary side liquid circulation line 13. The second temperature sensor 121 is disposed in the secondary side input pipe 119 to sense the temperature of the liquid flowing in the secondary side input pipe 119. In other words, the second temperature sensor 121 measures the temperature of the liquid to be cooled circulate from the secondary side circulation pipe 13 to the distribution control device 11.

The logic controller 122 is electrically connected to the primary side control valve 114, the first pump 116, the second pump 118, the first temperature sensor 120, the second temperature sensor 121, the surrounding temperature sensor 123, and the surrounding humidity sensor 124 to control the primary side control valve 114, first pump 116, second pump 118, first temperature sensor 120, second temperature sensor 121, surrounding temperature sensor 123, and surrounding humidity sensor 124.

Referring to FIG. 1, the primary side liquid circulation pipe 10 includes a primary side liquid input tube 101, a primary side liquid output tube 102, at least one primary side liquid input branch tube 103, and at least one primary side liquid output branch tube 104. The primary side liquid input tube 101 is connected to the water input device, and one end of each primary side liquid input branch tube 103 is connected to the primary side liquid input pipe 101, and the other end thereof is connected to the primary side input end of the distribution control device 11, in other words, each of the other end of the primary side liquid input branch tube 103 is connected to the primary side input pipe 112. One end of each primary side liquid output branch tube 104 is connected to the primary side liquid output pipe 102, and the other end thereof is connected to the primary side output end of the distribution control device 11, in other words, the other end of each primary side liquid output branch tube 104 is connected to the primary side output pipe 113.

The water filling device, the primary side liquid input pipe 101, the at least one primary side liquid input branch tube 103, the distribution control device 11, the at least one primary side liquid output branch tube 104, and the primary side liquid output pipe 102 form a flow path of the first cooling liquid. The water filling device supplies a first cooling liquid to the primary side liquid input pipe 101, and the first cooling liquid flows into the distribution control device 11 through the primary side liquid input pipe 101 and the at least one primary side liquid input branch tube 103, and enters the distribution control device 11. The first cooling liquid exchanges heat with the liquid to be cooled in the distribution control device 11. The first cooling liquid been through heat-exchange is then output to the outside through the at least one primary side liquid output branch tube 104 and the primary side liquid output pipe 102. The water filling device continuously supplies the new first cooling liquid to the distribution control device 11 to renew the first cooling liquid in the distribution control device 11, ensuring that the temperature of the first cooling liquid is continuously maintained at the preset temperature, thereby ensuring the heat exchange efficiency of the distribution control device 11.

The secondary side liquid circulation pipe 13 includes a secondary side liquid input pipe 131, a secondary side liquid output pipe 132, at least one secondary side liquid input branch tube 133, and at least one secondary side liquid output branch tube 134. The secondary side liquid input pipe 131 and the secondary side liquid output pipe 132 are respectively connected to the secondary side output end and the secondary side input end of the distribution control device 11, in other words, the secondary side liquid input pipe 131 is connected to the secondary side output pipe 117 of the distribution control device 11, and the secondary side output pipe 132 are connected to the secondary side input line 119 of the distribution control device 11. One end of each of the secondary side liquid input branch tubes 133 is connected to the secondary side liquid input pipe 131, and one end of each of the secondary side liquid output branch tubes 134 is connected to the secondary side liquid output pipe 132.

The primary side liquid input pipe 101 and the primary side liquid output pipe 102 of the primary side liquid circulation pipe 10, and the secondary side liquid input pipe 131 and the secondary side liquid output pipe 132 of the secondary side liquid circulation pipe 13 are rigid tube. At least one primary side liquid input branch tube 103 and at least one primary side liquid output branch tube 104 of the primary side liquid circulation pipe 10, and at least one secondary side liquid input branch tube 133 and at least one secondary side output branch tube 134 of the secondary side liquid circulation pipe 13 use a flexible tube to insert into the distribution control device 11 and the cabinet server 2.

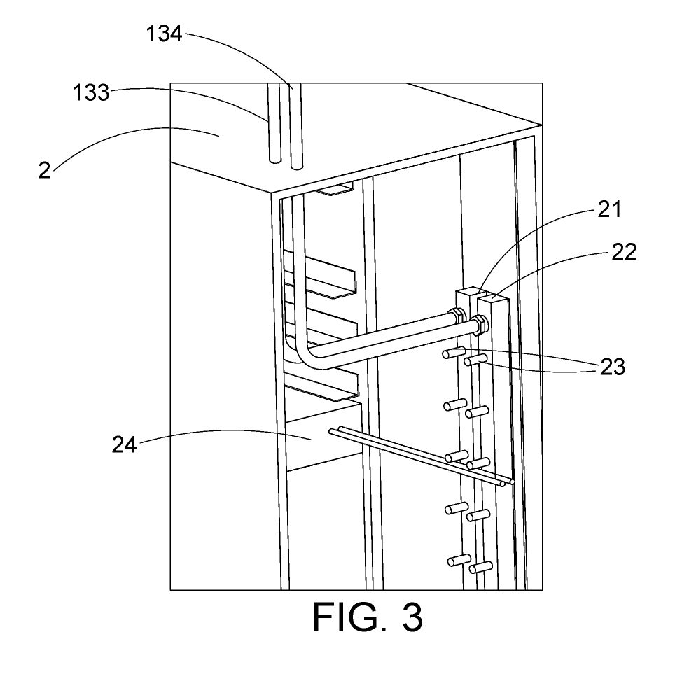

Referring to FIG. 3 again, a schematic diagram of a secondary side liquid circulation pipe connected to a cabinet server according to an embodiment of the present disclosure; as shown in the drawing, each of the other end of the secondary side liquid input branch tube 133 and a secondary side liquid output branch tube 134 is connected to each of the cabinet server 2. Each of the cabinet server 2 has a liquid input pipe joint 21 and a liquid output pipe joint 22, and each secondary side liquid input branch tube 133 is connected to a liquid input pipe joint 21 of the corresponding cabinet server 2, each of the secondary side liquid output branch tube 134 is connected to the liquid output pipe connector 22 of the corresponding cabinet server 2.

The liquid input pipe joint 21 has a plurality of connecting heads 23 and a circulation space (not shown) communicating with the plurality of connecting heads 23, and each of the secondary side liquid input branch tubes 133 is connected to one of the plurality of connecting heads 23 of the liquid input pipe joints 21. Similarly, the liquid output pipe joints 22 also has a plurality of connecting heads 23 and a circulation space (not shown) that communicates with the plurality of connecting heads 23, and each of the secondary liquid output branch tubes 134 is connected to one of the plurality of connectors 23 of the liquid output pipe joints 22.

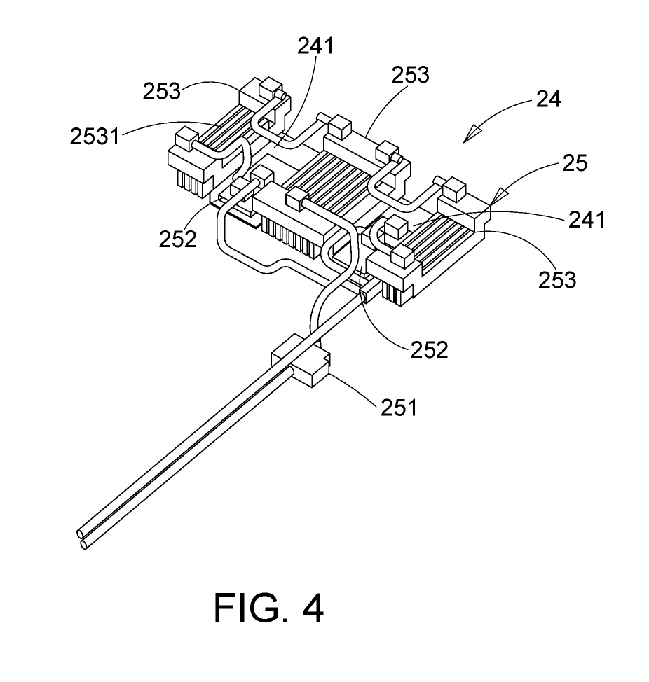

Please refer to FIG. 4, a schematic diagram of a server according to an embodiment of the present disclosure. As shown in the figure, each cabinet server 2 includes a plurality of servers 24 , each of which has a liquid cooling module 25, and the liquid cooling module 25 has a liquid input joint 251, at least one cooling plate 252 and at least one liquid flow block 253, at least one cooling plate 252 is disposed on the heat generating element 241 of the server 24, and the liquid input joint 251 is connected to one of the plurality of connecting heads 23 of the liquid input pipe joint 21 through a pipeline, and is connected to at least one cooling plate 252 by a pipeline, at least one cooling plate 252 is connected to at least one liquid flow block 253 by a pipeline, and at least one liquid flow block 253 is connected to one of the plurality of connectors 23 of the liquid output pipe joint 22 through a pipeline. The heat generating element 241 is an electronic component that generates thermal energy. The inside of the cooling plate 252 and the liquid flow block 253 respectively have a liquid circulation space, and the surface of the liquid flow block 253 has a plurality of heat dissipation fins 2531

The server 24 of the present embodiment has two heat generating elements 241, wherein the heating generating elements 241 are processors. Cooling plates 252 are respectively disposed on the two heating elements 241. Three liquid flow blocks 253 are disposed in the server 24, and two heat generating elements 241 are disposed between the three liquid flow blocks 253. In other words, each of the heat generating elements 241 is disposed between the adjacent two liquid flow blocks 253. The cooling plate 252 disposed on the heat generating element 241 is located between the adjacent two liquid flow blocks 253. The liquid input joint 251 connects two cooling plates 252 through pipelines, and the two cooling plates 252 respectively connect two liquid flow blocks 253 on the left and right sides through the pipeline, and two liquid flow blocks 253 on the left and right sides respectively connects the liquid flow block 253 located in the middle by a pipeline, and the liquid flow block 253 located in the middle connects one of the plurality of joints 23 of the liquid output pipe joint 22 through a pipeline.

When the liquid cooling system 1 of the present embodiment is in use, the first pump 116 draws the liquid in the water filling device to the water tank 115, the liquid in the water tank 115 is referred to as the second cooling liquid, and then the second pump 118 extracts the second cooling liquid in the water tank 115 to the secondary side output pipe 117. The second cooling liquid flows through the secondary side output pipe 117 to the secondary side liquid input pipe 131 of the secondary side liquid circulation pipe 13, and the second cooling liquid in the secondary side liquid input pipe 131 passes the secondary side liquid input branch tube 133 enters the liquid input pipe joint 21 of the corresponding cabinet server 2. The second cooling liquid in the liquid input pipe joint 21 flows into at least one of the servers 24 in the cabinet server 2, and the second cooling liquid carries away the heat energy generated by the at least one server 24, reducing the temperature of at least one of the servers 24.

The first pump 116 is used for the first time using the liquid cooling system 1, and then operated by the second pump 118 to circulate the second cooling liquid in the distribution device 11 and the secondary side liquid circulation pipe 13.

At the same time, the water filling device supplies the first cooling liquid to the primary side liquid input pipe 101 of the primary side liquid circulation pipe 10, and the primary side liquid input pipe 101 outputs the first cooling liquid through the at least one primary side liquid input branch pipe 103 through the primary side input pipe 112 to the distribution control device 11, the first cooling liquid flows into the heat exchanger 111 through the primary side input pipe 112.

When the liquid to be cooled enters the heat exchanger 111, the liquid to be cooled exchanges heat with the first cooling liquid, and the temperature of the liquid to be cooled is restored to a preset temperature of the second cooling liquid to generate a new second cooling liquid. The new second cooling liquid then enters at least one of the cabinet servers 2 through the above process, and carries away the heat energy generated by the heating elements 241 of each of the servers 24, reducing the temperature of at least one of the cabinet servers 2.

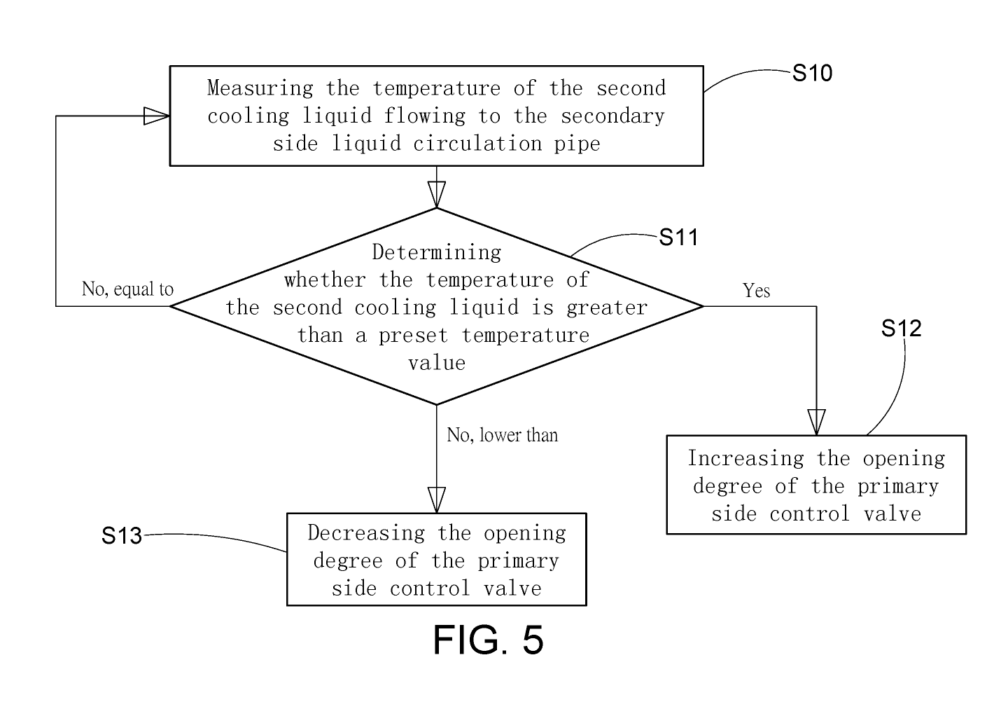

The liquid cooling system 1 of the present embodiment is mainly controlled by the distribution control device 11, and the automatic control method includes two types of temperature control and flow rate control. Please refer to FIG. 5, which is a flowchart of temperature control of the distribution control device according to an embodiment of the present disclosure. As shown in the figure, when the liquid cooling system 1 is in operation, step S10 is performed first, and the distribution control device 11 is cooled. The first temperature sensor 120 measures the temperature of the second cooling liquid flowing to the secondary side liquid circulation pipe 13 through the secondary side output pipe 117, and generates a first temperature signal to the logic controller 122. Next, in step S11, the logic controller 122 gets the temperature of the second cooling liquid sent to the secondary side liquid circulation pipe 13 according to the first temperature signal, and determines whether the temperature of the second cooling liquid is greater than a preset temperature value. When the temperature of the second cooling liquid is greater than the preset temperature value, indicating that the heat exchange amount of the heat exchanger 111 is lower than the preset heat exchange amount, step S12 is performed to increase the opening degree of the primary side control valve 114. The method to increase the opening degree of 114 is that the logic controller 122 generates a first control signal and transmits a first control signal to the primary side control valve 114, and the primary side control valve 114 increases its opening degree according to the first control signal, so that the flow rate of the first cooling liquid flowing into the primary side liquid circulation pipe 10 in the heat exchanger 111 is increased to add a large amount of the first cooling liquid from the primary side liquid circulation pipe 10 to the heat exchanger 111, so that the heat exchange amount of the heat exchanger 111 is returned to the preset heat exchange amount.

If the temperature of the second cooling liquid is less than the preset temperature value, indicating that the heat exchange amount of the heat exchanger 111 is higher than the preset heat exchange amount, step S13 is performed to reduce the opening degree of the primary side control valve 114. The method of decreasing the opening degree of the side control valve 114 is that the logic controller 122 generates a first control signal and transmits a first control signal to the primary side control valve 114, and the primary side control valve 114 reduces the opening degree according to the first control signal, so that the flow rate of the first cooling liquid in the heat exchanger 111 flowing out to the primary side liquid circulation pipe 10 is reduced to add a small amount of the first cooling liquid from the primary side liquid circulation pipe 10 into the heat exchanger 111, and let the amount of heat exchange in the heat exchanger 111 returns to the preset heat exchange amount. If the temperature of the second cooling liquid is equal to the preset temperature value, then return to step S10.

The above compares the temperature of the two cooling liquids outputted to the secondary side liquid circulation pipe 13 with a preset temperature value to determine the heat exchange amount of the heat exchanger 111, and if the heat exchange amount of the heat exchanger 111 is found to be lower than or higher than the preset heat exchange amount, the temperature of the first cooling liquid located in the heat exchanger 111 is maintained at a preset temperature value by controlling the flow rate of the first cooling liquid input to the heat exchanger 111 in the primary side liquid circulation pipe 10. In addition, the surrounding temperature sensor 123 and the surrounding humidity sensor 124 measure the temperature and humidity in the environment, respectively generate a surrounding temperature signal and a surrounding humidity signal, and transmit the surrounding temperature signal and the surrounding humidity signal to the logic controller 122. The logic controller 122 calculates a dew point temperature according to the surrounding temperature signal and the surrounding humidity signal, and the dew point temperature is a lower limit of the preset temperature value of the second cooling liquid, and prevents the temperature of the first and second cooling liquids outputted to the secondary side liquid circulation pipe 13 from being too low that causes the server 24 in the cabinet server 2 exposed and damaged.

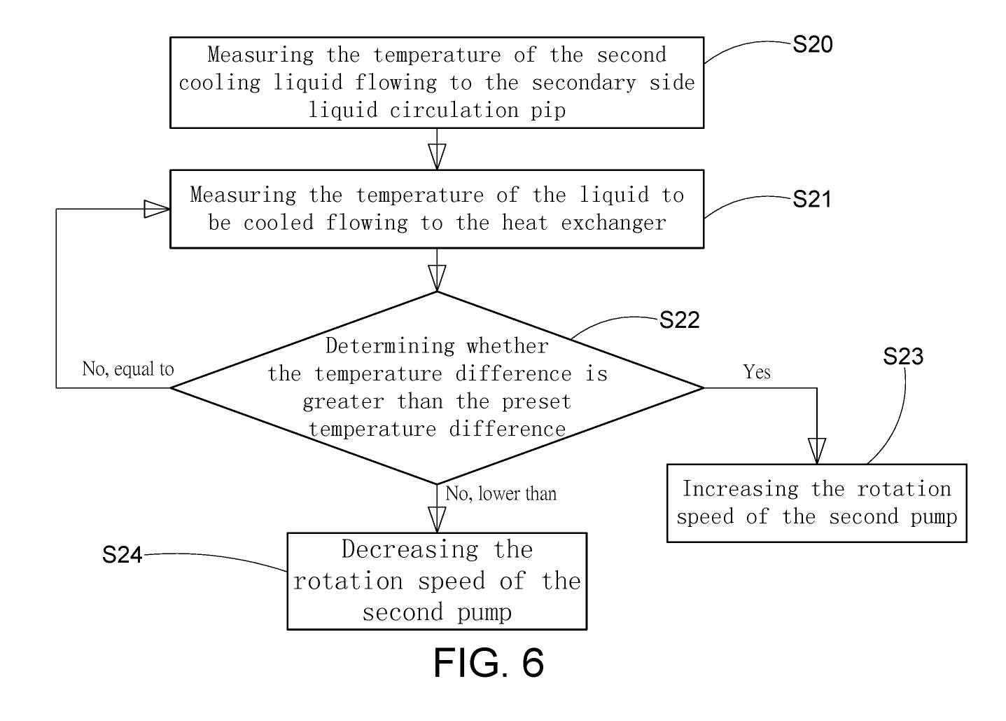

Please refer to FIG. 6, which is a first mode flowchart of the flow control of the distribution control device according to an embodiment of the present disclosure. As shown in the figure, when the liquid cooling system 1 is in operation, step S20 is performed first, and the first temperature sensor 120 is executed to measure the temperature of the second cooling liquid flowing to the secondary side circulation pipe 13 of the heat exchanger 111, and generates a first temperature signal to the logic controller 122; while performing step S21, the second temperature sensor 121 measures the temperature of the liquid to be cooled in the secondary side circulation pipe 13 of the heat exchanger 111, and generates a second temperature signal to the logic controller 122.

Next, in step S22, the logic controller 122 calculates a temperature difference between the temperature of the second cooling liquid and the temperature of the liquid to be cooled according to the first temperature signal and the second temperature signal. Then, in step S23, the logic controller 122 determines whether the temperature difference is greater than the preset temperature difference. If the temperature difference is greater than the preset temperature difference, it indicates that the temperature of the second cooling liquid that the heat exchanger 111 supplies to the secondary side liquid circulation line 13 is too low. If the temperature is lower, step S24 is performed to increase the rotation speed of the second pump 118. The method of increasing the rotation speed of the second pump 118 is that the logic controller 122 generates a third control signal and transmits a third control signal to the second pump 118. The pump 118 increases its rotational speed according to the third control signal to increase the flow rate of the second cooling liquid supplied from the heat exchanger 111 to the secondary side liquid circulation pipe 13, and also accelerates the supply of the second cooling liquid to the secondary side of the heat exchanger 111 through the liquid circulation pipe 13, thus shortens the time during which the liquid to be cooled undergoes heat exchange.

If it is determined that the temperature difference is less than the preset temperature difference, indicating that the temperature of the second cooling liquid supplied to the secondary side liquid circulation line 13 by the heat exchanger 111 is too high, step S25 is performed to lower the rotation speed of the second pump 118, and the method of lowering the rotational speed of the second pump 118 is that the logic controller 122 generates a fourth control signal and transmits a fourth control signal to the second pump 118, and the second pump 118 lowers its rotational speed according to the fourth control signal to reduce the flow rate of the second cooling liquid supplied from the heat exchanger 111 to the secondary side liquid circulation pipe 13, that is, lower the rate at which the heat exchanger 111 supplies the second cooling liquid to the secondary side liquid circulation pipe 13, and increases the time during which the liquid to be cooled is subjected to heat exchange. If it is determined that the temperature difference is equal to the preset temperature difference, then return to step S20.

The flow rate of the second cooling liquid supplied to the secondary side liquid circulation pipe 13 by the heat exchanger 111 is determined to be supplied to the heat exchanger 111 with respect to the secondary side liquid circulation pipe 13 by comparing the difference value with the preset pressure difference value. According to the flow rate of the liquid to be cooled, the rotation speed of the second pump 118 is controlled by the logic controller 122, the flow rate of the second cooling liquid supplied to the heat exchanger 111 to the secondary side liquid circulation pipe 13 is adjusted, and the heat exchange is performed. The flow rate of the second cooling liquid supplied to the heat exchanger 111 by the secondary side liquid circulation pipe 13 is the same as the flow rate of the liquid to be cooled supplied from the secondary side liquid circulation line 13 to the heat exchanger 111, ensuring stable operation of the liquid cooling system 1.

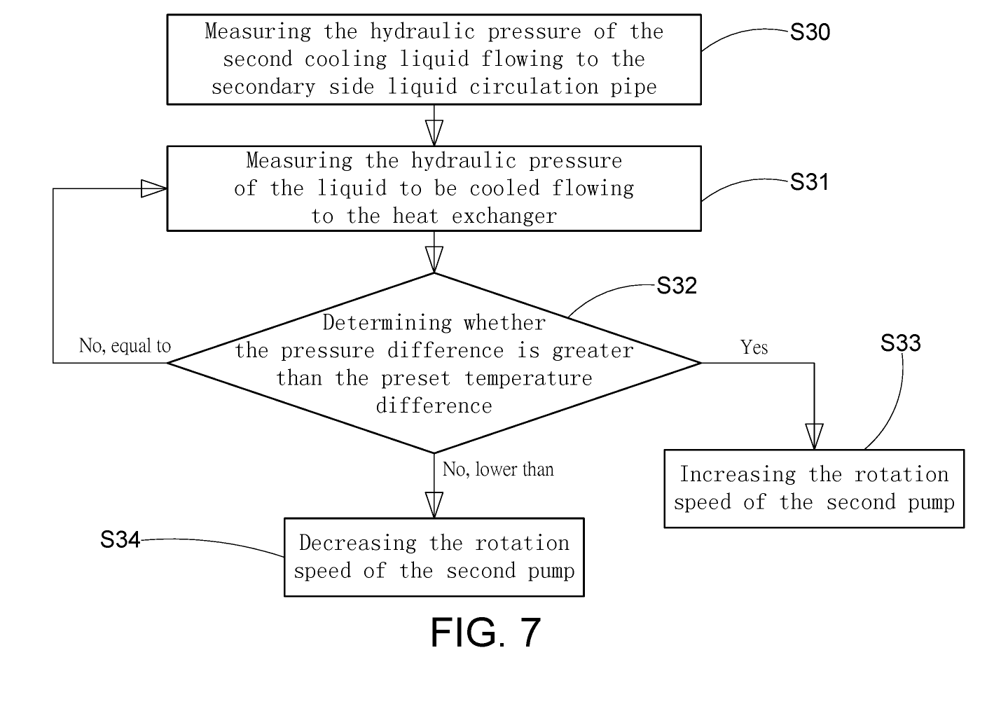

Referring to FIG. 3, the distribution control device 11 of the present embodiment further includes a first pressure sensor 125 and a second pressure sensor 126. The first pressure sensor 125 is disposed on the secondary side output pipe 117, and the second pressure sensor 126 is disposed on the secondary side input line 119, the first pressure sensor 125 and the second pressure sensor 126 are electrically connected to the logic controller 122. Please refer to FIG. 7, which is a second mode flowchart of the flow control of the distribution control device according to an embodiment of the present disclosure. As shown in the figure, when the liquid cooling system 1 is in operation, step S30 is performed first. The pressure sensor 125 measures the hydraulic pressure of the second cooling liquid supplied from the heat exchanger 111 to the secondary side circulation pipe 13 and generates a first pressure signal to the logic controller 122; while performing step S31, the second pressure sensor 126 measures the hydraulic pressure of the liquid to be cooled supplied by the secondary side liquid circulation pipe 13 to of the heat exchanger 111, and generates a second pressure signal to the logic controller 122.

Next, in step S32, the logic controller 122 calculates a pressure difference between the hydraulic pressure of the second cooling liquid and the hydraulic pressure of the liquid to be cooled according to the first pressure signal and the second pressure signal. The logic controller 122 determines whether the pressure difference value is greater than a preset pressure difference value, and the pressure difference value is greater than the preset pressure difference value, indicating the flow rate that the heat exchanger 111 supplies the second cooling liquid to the secondary side liquid circulation pipe 13 is too large, step S33 is executed to reduce the rotation speed of the second pump 118, and the rotation speed of the second pump 118 is decreased. The logic controller 122 generates a fifth control signal and transmits a fifth control signal to the second pump 118. The fifth control signal lowers its rotational speed to reduce the flow rate of the second cooling liquid supplied from the heat exchanger 111 to the secondary side liquid circulation pipe 13.

If it is determined that the pressure difference is less than the preset pressure difference, indicating that the flow rate of the second cooling liquid supplied to the secondary side liquid circulation pipe 13 by the heat exchanger 111 is too small, step S34 is performed to increase the rotation speed of the second pump 118. The method of increasing the rotational speed of the second pump 118 is that the logic controller 122 generates a sixth control signal and transmits a sixth control signal to the second pump 118, and the second pump 118 decreases its rotational speed according to the sixth control signal to increase the flow rate of the second cooling liquid supplied to the secondary side liquid circulation pipe 13 to the heat exchanger 111. If it is determined that the pressure difference value is equal to the preset pressure difference value, then return to step S30.

The flow rate of the second cooling liquid supplied to the secondary side liquid circulation pipe 13 by the heat exchanger 111 is determined to be supplied to the heat exchanger according to the flow rate of the liquid to be cooled supplied by the heat exchanger 111 to secondary side liquid circulation pipe 13 by comparing the pressure difference value with the preset pressure difference value, the rotation speed of the second pump 118 is controlled by the logic controller 122, the flow rate of the second cooling liquid supplied to the secondary side liquid circulation pipe 13 by the heat exchanger 111 is adjusted. The flow rate of the second cooling liquid supplied from the exchanger 111 to the secondary side liquid circulation pipe 13 is the same as the flow rate of the liquid to be cooled supplied from the secondary side liquid circulation pipe 13 to the heat exchanger 111, ensuring stable operation of the liquid cooling system 1. The above mode is mainly used for inserting or removing part of the pipeline of the secondary side liquid circulation pipe 13 into the cabinet server 2, that is, when the cabinet server 2 is plugged and unplugged and maintained, the liquid flow rate through of the other cabinet server 2 basically do not change, thus to ensure safe operation.

In summary, according to the technical solution of the present disclosure, the cabinet server is cooled by liquid cooling, the energy efficiency ratio of the liquid cooling system is below 1.3, there is almost no noise, no low filling water temperature is needed, natural cooling source is fully utilized, and the cooling tower can be used to meet the cooling needs. The application uses liquid cooling to cool the air conditioning system, and the liquid cooling system occupies less space in the cabinet server, so that the cabinet server can accommodate more servers. The liquid cooling system of the present disclosure has a good cooling capacity, improves the heat flux density of the data center of the machine, saves the floor space, and is not restricted by altitude and geography, and can work normally anywhere.

The above is only an embodiment of the present disclosure and is not intended to limit the disclosure. Various changes and modifications can be made to the present disclosure by those skilled in the art. Any modifications, equivalents, improvements, etc. made within the spirit and scope of the disclosure are intended to be included within the scope of the appended claims.

What is claimed is:

1. A liquid cooling system for cabinet server, comprising:
a primary side liquid circulation pipe, connected to a water filling device;
a distribution control device, connected to the primary side liquid circulation pipe; and
a secondary side liquid circulation pipe, connected to the distribution control device and at least one cabinet server;
wherein the primary side liquid circulation pipe inputs a first cooling liquid to the distribution control device, and the secondary side liquid circulation pipe outputs a second cooling liquid to each of the at least one cabinet server, the second cooling liquid flowing through at least one server of a corresponding one of the at least one cabinet server, the cabinet server outputs a liquid to be cooled to the secondary liquid circulation pipe, and the liquid to be cooled passes through the secondary liquid circulation pipe to the distribution control device, the first cooling liquid and the liquid to be cooled have heat exchange in the distribution control device, the distribution control device outputs the cooling liquid that has gone through said heat exchange to the secondary side liquid circulation pipe.

2. The liquid cooling system for a cabinet server according to claim 1, wherein the primary side liquid circulation pipe comprises a primary side liquid input tube, a primary side liquid output tube, at least a primary side liquid input branch tube, and at least a primary side liquid output branch tube, the primary side liquid input tube is connected to the water filling device, and the at least one primary side liquid input branch tube is connected to the primary side liquid input tube and a primary side input end of the distribution control device, the at least one primary side liquid output branch tube connects the primary side liquid output tube and a primary side output end of the distribution control device.

3. The liquid cooling system for a cabinet server according to claim 1, wherein the secondary side liquid circulation pipe comprises a secondary side liquid input tube, a secondary side liquid output tube, at least a secondary side liquid input branch tube and at least a secondary side liquid output branch tube, wherein the secondary side liquid input tube and the secondary side liquid output tube are respectively connected to a secondary liquid output end and a secondary liquid input end of the distribution control device, the at least one secondary side liquid input branch tube is connected to the secondary side liquid input tube and a liquid input pipe joint of the corresponding cabinet server, and the at least one secondary side liquid output branch tube is connected to the secondary side liquid output tube and a liquid output pipe joints of the corresponding cabinet server.

4. The liquid cooling system for a cabinet server according to claim 3, wherein each of the liquid input pipe joint and the liquid output pipe joint comprises a plurality of connectors and a circulation space for the plurality of connectors, each of the at least one secondary side liquid input branch tube connecting one of the plurality of connectors of the liquid input pipe joint, each of the at least one secondary side liquid output branch tube connecting one of the plurality of connectors of the liquid output pipe joint.

5. A liquid cooling system for a cabinet server according to claim 4, wherein each of the cabinet servers comprises a plurality of servers, each of the servers has a liquid cooling module, the liquid cooling module has a liquid input connector, at least a cooling plate and at least a liquid flow block, at least one of the cooling plate is disposed on a heat generating component of the server, and the liquid input connector is connected to one of the plurality of connectors of the liquid input pipe joint through a pipeline, the liquid input pipe joint is connected to the at least one cooling plate through a pipeline, the at least one cooling plate connects the at least one liquid flow block through a pipeline, and the at least one liquid flow block connects one of the plurality of connectors of the liquid output pipe joint through a pipeline.

6. The liquid cooling system for a cabinet server according to claim 1, wherein the distribution control device comprises a heat exchanger, a primary side liquid input tube, a primary side liquid output tube, a primary side control valve, a water tank, a first pump, a secondary side liquid output tube, a second pump, a secondary side liquid input tube, a first temperature sensor, a second temperature sensor, a logic controller, an surrounding temperature sensor, and an surrounding humidity sensor; one end of the primary side liquid input tube and one end of the primary side liquid output tube are respectively connected to the heat exchanger, and the other ends thereof are respectively connected to a primary side liquid input tube and a primary side liquid output tube of the primary side liquid circulation pipe, and the primary side control valve is connected between the primary side liquid input tube and the primary side liquid output tube; the water tank is connected to the heat exchanger, the first pump is connected to the water tank and the water filling device, the second pump is connected to the water tank through a pipeline, and the secondary side liquid output tube is connected to the second pump and the secondary side liquid input tube of the secondary side liquid circulation pipe, the secondary side liquid input tube connects with the heat exchanger and the secondary side liquid output tube of the secondary side liquid circulation pipe, the first temperature sensor is disposed at the secondary side liquid output tube, the second temperature sensor is disposed at the secondary side liquid input tube, and the logic controller is electrically connected to the primary side control valve, the first pump, the second pump, the first temperature sensor, the second temperature sensor, the surrounding temperature sensor, and the surrounding humidity sensor.

7. The liquid cooling system for a cabinet server according to claim 6, wherein the first temperature sensor measures a temperature of the second cooling liquid supplied to the secondary side circulation pipe, and generates a first temperature signal to the logic controller, the logic controller generates a first control signal to the primary side control valve when the logic controller determines that the temperature of the second cooling liquid to be cooled is higher than a preset temperature value, the primary side control valve increases its opening according to the first control signal; the logic controller generates a second control signal to the a primary side control valve when the logic controller determines that the temperature of the second cooling liquid is less than the preset value, the primary side control valve reduces its opening according to the second control signal; wherein the preset value is the dew point temperature calculated according to the surrounding temperature detected by the logic controller according to the surrounding temperature sensor and the surrounding humidity detected by the surrounding humidity sensor.

8. The liquid cooling system for a cabinet server according to claim 6, wherein the first temperature sensor measures a temperature of the second cooling liquid supplied to the secondary side circulation pipe, and generates a first a temperature signal to the logic controller; the second temperature sensor measures a temperature of the liquid to be cooled input by the secondary side circulation pipe, and generates a second temperature signal to the logic controller; the logic control calculates a temperature difference between the temperature of the second cooling liquid and the temperature of the liquid to be cooled according to the first temperature signal and the second temperature signal; the logic controller generates a third control signal to the second pump when the logic controller determines that the temperature difference is greater than a preset temperature difference, the second pump increases its rotational speed according to the third control signal; the logic controller generates a fourth control signal to the second pump when the logic controller determines that the temperature difference is less than the preset value, the second pump lowers its rotational speed according to the fourth control signal.

9. The liquid cooling system for a cabinet server according to claim 6, wherein the distribution control device further comprises a first pressure sensor and a second pressure sensor, wherein the first pressure sensor is disposed at the second side liquid output tube, the second pressure sensor is disposed at the second side liquid input tube, and the first pressure sensor and the second pressure sensor are electrically connected to the logic controller.

10. The liquid cooling system for a cabinet server according to claim 9, wherein the first pressure sensor measures a hydraulic pressure of a second cooling liquid supplied to the secondary side circulation pipe, and generates a first pressure signal to the logic controller; the second pressure sensor measures a hydraulic pressure of the liquid to be cooled input by the secondary side circulation pipe, and generates a second pressure signal to the logic controller; the logic control calculates a pressure difference between the hydraulic pressure of the second cooling liquid and the hydraulic pressure of the liquid to be cooled according to the first pressure signal and the second pressure signal; the logic controller generates a fifth control signal to the second pump when the logic controller determines that the pressure difference is greater than a preset a differential pressure value, the second pump lowers its rotational speed according to the fifth control signal; the logic controller generates a sixth control signal to the second pump when the logic controller determines that the pressure difference value is less than the preset pressure difference value, the second pump increases its rotational speed according to the sixth control signal.
